(19) United States
(12) Patent Application Publication
(10) Pub. No.: US 2008/0025822 A1
(43) Pub. Date: Jan. 31, 2008

(54) DEVICE AND METHOD FOR HANDLING AN OBJECT OF INTEREST USING A DIRECTIONAL ADHESIVE STRUCTURE

(76) Inventors: Sangbae Kim, Stanford, CA (US); Jin Lee, Palo Alto, CA (US)

Correspondence Address: Wilson & Ham;PMB: 348, 2530 Berryessa Road, San Jose, CA, 95132, US

(21) Appl. No.: 11/735,985

(22) Filed: Apr. 16, 2007

Related U.S. Application Data
(60) Provisional application No. 60/792,761, filed on Apr. 17, 2006.

(30) Foreign Application Priority Data
Mar. 15, 2007 (KR) 10-2007-0025602

(51) Int. Cl. B32B 33/00; B29C 45/00; H01L 21/677

(52) U.S. Cl. 414/217.1; 264/328.1; 414/800; 428/90

(57) ABSTRACT

A device and method for handing an object of interest uses one or more directional adhesive structures to adhere to the object using van der Waals forces. Each of the directional adhesive structures includes hair-like features with angled contact surfaces. The directional adhesive structures are configured such that the angled contact surfaces of the hair-like features adhere to a surface of the object using van der Waals forces when at least one force is applied to each of the base plates in a direction substantially parallel with respect to the surface of the object.

### CROSS REFERENCE TO RELATED APPLICATION

This application is entitled to the benefit of U.S. Provisional Patent Application Ser. No. 60/792,761 filed on Apr. 17, 2006 and Korean Patent Application No. 10-2007-0025602 filed in the Korean Intellectual Property Office on Mar. 15, 2007, which are both incorporated herein by reference.

### BACKGROUND OF THE INVENTION

During fabrication of some silicon-based devices, there is a need to bond two structures, e.g., semiconductor wafers, thin-film plates, glass plates and liquid crystal display (LCD) panels, organic light emitting diode (OLED) panels, optical pick-up lenses and low pass filters (LPFs) for digital cameras. Silicon wafer bonding technologies, such as anodic, direct, and intermediate-layer bonding techniques, have been developed to address this need. These silicon wafer bonding technologies normally require high temperature annealing process to produce a strong bond between the two structures being bonded. However, this high temperature annealing process is a source of many device failures.

In order to overcome this concern, bonding techniques in vacuum have been developed to lower the required high temperature, which also have an added benefit of achieving bubble-free bonding. These vacuum bonding techniques are becoming widely used in many industries, such as semiconductor, display, Micro-Electro-Mechanical-Systems (MEMS), System on Chip (SoC) and Silicon on Insulator (SOI) industries. Along with the development of vacuum bonding technology, there is also growing interests in handling modules to handle the structures being bonded in vacuum in order to lift, transport and/or reverse the structures. Currently, the most widely used handling modules are Electric Static Chucks (ESCs), which use electrostatic force to hold or clamp a structure of interest, such as silicon wafer.

A concern with ESCs is that these chucks are relatively expensive due to advanced coating technology needed to manufacture the ESCs. Another concern is that the electric fields created by the ESCs may lead to device failures.

Thus, there is a need for an object handling module that addresses the above concerns of cost and device failure with respect to ESCs.

### SUMMARY OF THE INVENTION

A device and method for handing an object of interest uses one or more directional adhesive structures to adhere to the object using van der Waals forces. Each of the directional adhesive structures includes hair-like features with angled contact surfaces. The directional adhesive structures are configured such that the angled contact surfaces of the hair-like features adhere to a surface of the object using van der Waals forces when at least one force is applied to each of the base plates in a direction substantially parallel with respect to the surface of the object.

A device for handing an object of interest in accordance with an embodiment of the invention comprises a plurality of base plates, a drive mechanism and a plurality of directional adhesive structures. The drive mechanism is connected to the base plates to apply forces to the base plates. The plurality of directional adhesive structures is attached to the base plates. Each of the directional adhesive structures includes a base structure and hair-like features attached to the base structure. The hair-like features have angled contact surfaces such that the angled contact surfaces adhere to a surface of the object using van der Waals forces when at least one force is applied to each of the base plates in a particular direction substantially parallel with respect to an outer surface of the base structure of that base plate.

A method for handling an object of interest in accordance with an embodiment of the invention comprises providing a plurality of base plates with directional adhesive structures, the directional adhesive structures including hair-like features with angled contact surfaces, placing the base plates near the object such that some of the hair-like features of the directional adhesive structures are in contact with a surface of the object, and displacing each of the base plates in a particular direction substantially parallel with respect to the surface of the object such that the angled contact surfaces of the hair-like features adhere to the surface of the object using van der Waals forces.

A directional adhesive structure in accordance with an embodiment of the invention comprises a base structure, and a plurality of hair-like features attached to the base structure. Each of the hair-like features having a contact surface for adhesion using van der Waals forces. The hair-like features having a diameter greater than 50 microns.

A method of fabricating a directional adhesive structure comprises providing a first mold, a second mold and a third mold, the first mold including a space that corresponds to a base structure of the directional adhesive structure, the second mold including holes that correspond to hair-like features of the directional adhesive structure, the second mold further including V-shaped grooves, the third mold including V-shaped protrusions, attaching the second mold to the first mold, injecting liquid polymer into one or more of the holes of the second mold to fill the holes of the second mold and the space of the first mold with the liquid polymer, placing the third mold on the second mold such that the V-shaped protrusions are fitted into the V-shaped grooves of the second mold, and separating the first mold from the second mold to extract a solidified polymer structure in the form of the directional adhesive structure from the first, second and third molds.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of an object handing module in accordance with an embodiment of the invention and a variety of equipments into which the object handling device can be integrated.

FIG. 2 is an enlarged perspective view of the object handling module of FIG. 1.

FIG. 3 is a perspective view of a directional adhesive structure in accordance with an embodiment of invention, which can be used in the object handling module.

FIG. 4 is an enlarged cross-sectional view of a portion of the directional adhesive structure of FIG. 3.

FIGS. 5A-5D illustrate attaching and detaching operations of the object handling module in accordance with an embodiment of the invention.

FIGS. 6A and 6B illustrate a detaching operation of the object handling module in accordance with an alternative embodiment of the invention.

FIG. 7A is a bottom view of the object handling module with three base plates in accordance with an embodiment of the invention.

FIG. 7B is a bottom view of the object handling module with four base plates in accordance with an embodiment of the invention.

FIG. 7C is a bottom view of the object handling module in accordance with an embodiment of the invention, which uses tangential forces in angular directions.

FIG. 7D is a perspective bottom view of the object handling module in accordance with an embodiment of the invention, which has a low profile.

FIG. 8A is a perspective view of a set of molds that can be used to fabricate a directional adhesive structure in accordance with an embodiment of the invention.

FIG. 8B is a cross-sectional view of the set of molds shown in FIG.8A.

FIGS. 9A-9C illustrate a process for fabricating a directional adhesive structure in accordance with an embodiment of the invention.

FIG. 10 is a process flow diagram of a method for handing an object of interest in accordance with an embodiment of the invention.

FIG. 11 is a process flow diagram of a method for fabricating a directional adhesive structure in accordance with an embodiment of the invention.

### DETAILED DESCRIPTION

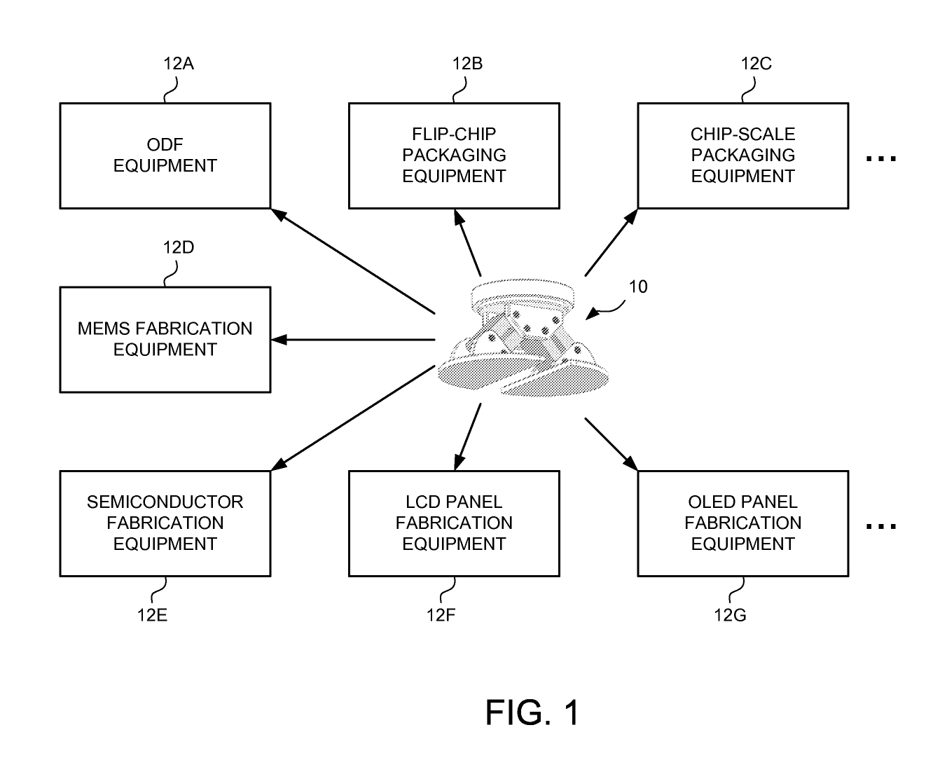

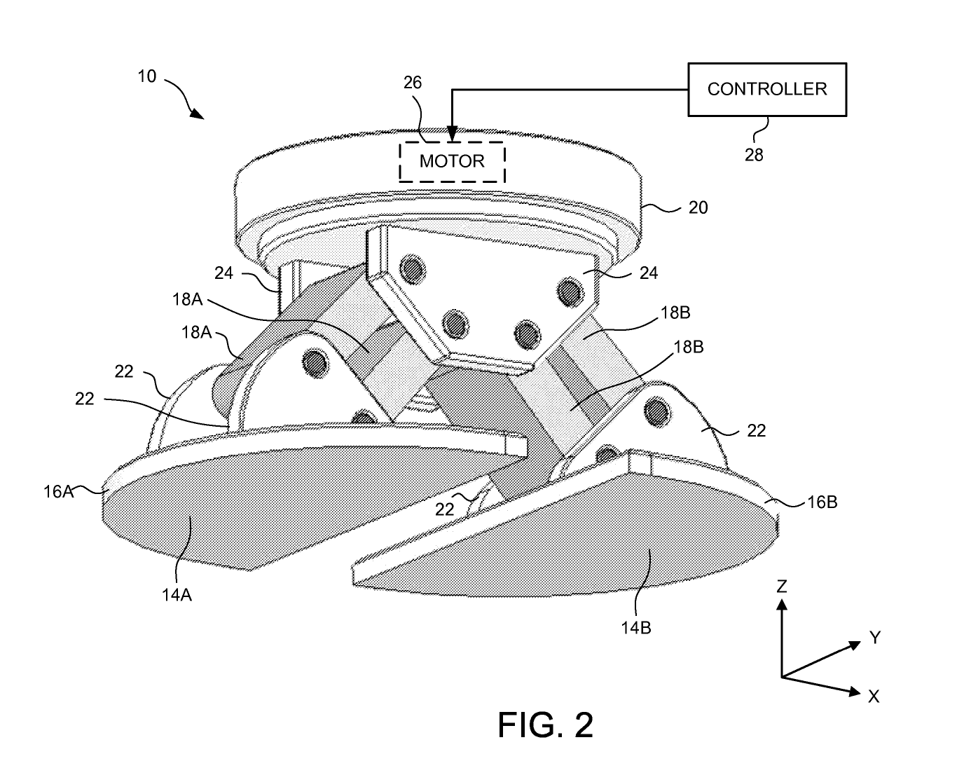

With reference to FIGS. 1 and 2, an object handling module 10 in accordance with an embodiment of the invention is described. As described in more detail below, the object handling module 10 is designed to use hold or clamp an object of interest, such as semiconductor wafers, thin-film plates, glass plates and liquid crystal display (LCD) panels, organic light emitting diode (OLED) panels, optical pick-up lenses and low pass filters (LPFs) for digital cameras, using van der Waals forces. Thus, the object handling module 10 can operate in a vacuum environment. However, unlike an Electric Static Chuck (ESC), the object handling module 10 can be made without using expensive fabrication technologies. In addition, since the object handling module 10 uses van der Waals forces rather than electrostatic forces, the possibility of device failures due to exposure to electric field and/or magnetic filed is significantly minimized.

As illustrated in FIG. 1, the object handling module 10 can be used in various fabrication equipments including, but is not limited to, One Drop Filling (ODF) equipment 12A, Flip-chip packaging equipment 12B, Chip-scale packaging equipment 12C, Micro-Electro-Mechanical-Systems (MEMS) fabrication equipment 12D, semiconductor fabrication equipment 12E, liquid crystal display (LCD) panel fabrication equipment 12F and organic light-emitting diode (OLED) panel fabrication equipment 12G. In fact, the object-handling module 10 can be used in any equipment where an object needs to be handled, for example, in order to hold, lift, transport and/or reverse the object. Thus, the object handling module 10 can be considered as a device that can be part of an overall system.

As shown in FIG. 2, which is an enlarged perspective view of the object handling module 10, the object handling module includes directional adhesive structures 14A and 14B, base plates 16A and 16B, arms 18A and 18B and a foundation plate 20. The directional adhesive structure 14A is attached to a bottom surface of the base plate 16A. Similarly, the directional adhesive structure 14B is attached to a bottom surface of the base plate 16B. As an example, the directional adhesive structures 14A and 14B may be attached to the bottom surfaces of the base plates 16A and 16B, respectively, using an adhesive material. As described in more detail below, the directional adhesive structures 14A and 14B are configured to provide controllable adhesion between the object handling module 10 and an object of interest using van der Waals forces to attach the object onto the object handling module and to release the object from the object handling module.

The base plates 16A and 16B provide structural support for the attached directional adhesive structures 14A and 14B to engage an object of interest. The base plate 16A is connected to the arms 18A, which are connected to the foundation plate 20. Similarly, the base plate 16B is connected to the arms 18B, which are also connected to the foundation plate 20. The base plates 16A and 16B are connected to the respective arms 18A and 18B so that the arms can apply forces to the base plates along an X-axis direction when the arms are moved accordingly. Consequently, the arms 18A and 18B can apply forces to the respective the base plates 16A and 16B in directions toward each other or in directions away from each other.

In the illustrated embodiment, each of the base plates 16A and 16B includes parallel fin-like members 22, which are separated by a distance to accommodate the arms 18A or 18B for that base plate. The arms 18A are connected to the parallel fin-like members 22 of the base plate 16A so that the base plate 16A can pivot relative to the arms 18A as the base plate 16 is linearly displaced by the movements of arms 18A. This allows the lower surface of the base plate 16A to remain substantially parallel to the X-Y plane as the base plate 16A is linearly displaced. Similarly, the foundation plate 20 includes parallel fin-like members 24, which are separated by a distance to accommodate the arms 18A and 18B. The arms 18A and 18B are connected to the parallel fin-like members 24 of the foundation plate 20 so that the arms can pivot relative to the foundation plate to linearly displace the base plates 16A and 16B along the X-axis direction. In this embodiment, each of the base plates 16A and 16B is connected to two arms, which are used to linearly displace the connected base plate. However, in other embodiments, each of the base plates 16A and 16B may be connected to a single arm or more than two arm.

As shown in FIG. 2, the foundation plate 20 houses a motor 26 to move the arms 18A and 18B in order to linearly displace the base plates 16A and 16B. The motor 26 can be any type of a motor that imparts motion. Thus, the arms 18A and 18B and the motor 26 are part of a drive mechanism that can displace the base plates 16A and 16B to apply forces to the base plates. The motor 26 is electrically connected to a controller 28, which controls the motor. The foundation plate 20 is configured to be attached to a structure of a main equipment system, such as the ODF equipment, other fabrication equipment or a mobile robotic system. The controller 28 may be part of the main equipment system. In other embodiments, the object handling module 10 may utilizes more than one motor to move the arms 18A and 18B.

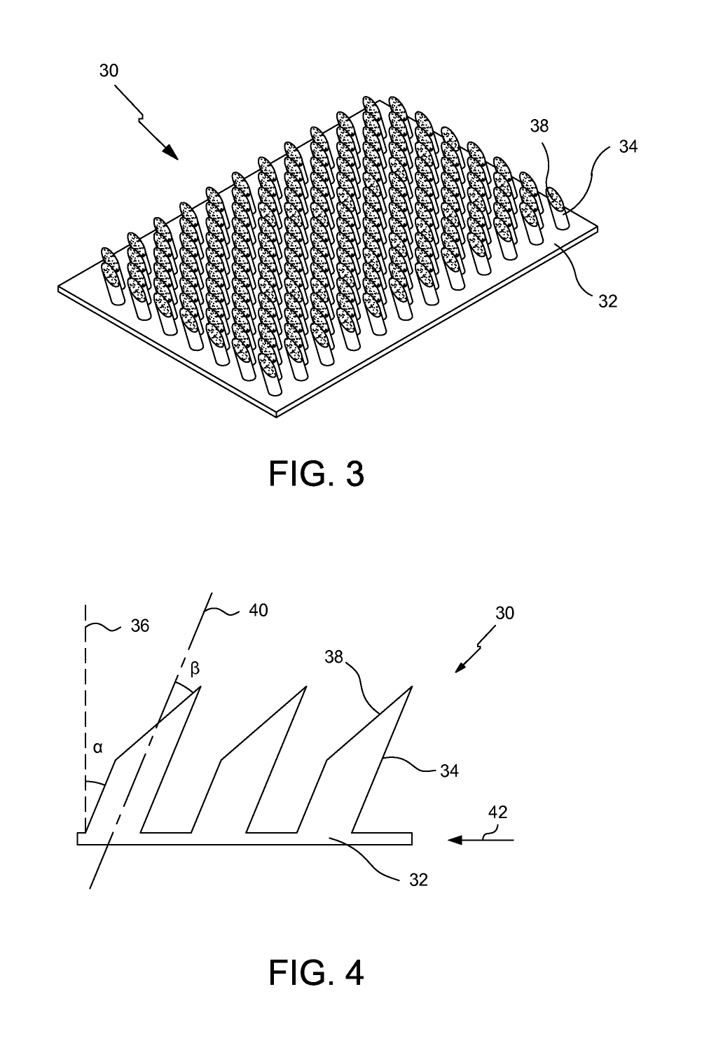

Turning now to FIG. 3, a directional adhesive structure 30 in accordance with an embodiment of the invention is shown. The directional adhesive structure 30 is an example of a structure that can be used for the directional adhesive structures 14A and 14B of the object handling module 10. The directional adhesive structure 30 includes a base structure 32 and anisotropic hair-like features 34. The anisotropic hair-like features 34 are used to controllably engage a surface of an object to create an adhesion between the directional adhesive structure 30 and the object using van der Waals forces. The anisotropic hair-like features 34 are configured to exhibit strong van der Waals forces when the ends of the anisotropic hair-like features are in contact with a surface of a target object and the base structure 32 is subjected to tangential force with respect to the outer or upper surface of the base structure in a particular preferred direction. In contrast, the anisotropic hair-like features 34 are configured to exhibit weaker van der Waals forces when the tangential force is removed or tangential force is applied in the opposite direction of the preferred direction. Thus, the anisotropic hair-like features 34 allow for selective attachment and detachment of an object using applied tangential force.

As shown in FIG. 4, which is an enlarged cross-sectional view of a portion of the directional adhesive structure 30, the anisotropic hair-like features 34 are slanted at an angle of α with respect to a normal line 36, which is normal to the outer surface of the base structure 32. The angle of α may be any angle between 5 and 45 degrees. As an example, the angle of α may be 20 degrees. Each anisotropic hair-like feature 34 has an angled end surface 38, which is the contact surface of that anisotropic hair-like feature that engages an object of interest. This contact surface 38 of the anisotropic hair-like feature 34 has an angle of β with respect to the central axis line 40 of that anisotropic hair-like feature. As such, the contact surface 38 has an angle of α+β with respect to the normal line 36. The angle of β may be any angle between 5 and 45 degrees. Thus, the angle of the contact surface 38 with respect to the normal line 36 may be any angle between 10 and 90 degrees. As an example, the angle of β may be 25 degrees, assuming that the angle of α is 20 degrees, which means that the angle of the contact surface 36 with respect to the normal line 36 is 45 degrees.

Since the contact surfaces 38 of the anisotropic hair-like features 34 are angled, the available surface area to engage an object of interest is significantly increased. Thus, the adhesive force between the anisotropic hair-like features 34 and the object can potentially be much stronger using the angled contact surfaces 38 when compared to non-angled contact surfaces because the strength of van der Waals forces is dependent on the total contacting surface area. Furthermore, since the anisotropic hair-like features 34 are angled with respect to the normal line 36, more area of the angled contact surfaces 38 of the anisotropic hair-like features 34 can engage the object when the anisotropic hair-like features are further angled due to tangential force applied to the base structure 32 in the preferred direction, as indicated by an arrow 42, which is a tangential direction away from the contact surfaces 38 of the anisotropic hair-like features 34. As used herein, tangential force is a force applied in a direction substantially parallel to the upper or outer surface of the base structure 32, which faces the anisotropic hair-like features 34. This tangential force can be one of several force components of an applied force. In operation, the outer surface of the base structure 32 is positioned relatively parallel to an upper surface of an object of interest. Thus, tangential force can also be viewed as a force applied in a direction substantially parallel to the upper surface of an object being handled.

The angle of the anisotropic hair-like features 34 and the angle of the contact surfaces 38 of the anisotropic hair-like features 34 provide controllability of adhesion between the anisotropic hair-like features and a target object due to van der Waals forces using directionality of applied tangential force. When tangential force is applied to the base structure 32 in the preferred direction, strong van der Waals forces are created between the contact surfaces 38 of the anisotropic hair-like features 34 and the target object. Thus, the target object can be easily attached to the contact surfaces 38 of the anisotropic hair-like features 34 by applying tangential force to the base structure 32 in the preferred direction. However, when tangential force is removed or applied to the base structure 32 in the opposite direction of the preferred direction, the van der Waals forces between the contact surfaces 38 of the anisotropic hair-like features 34 and the target object are decreased. Thus, the target object can easily be detached or released from the contact surfaces 38 of the anisotropic hair-like features 34 by removing the applied tangential force to the base structure 32.

In an embodiment, the anisotropic hair-like features 34 and the base structure 32 are formed together as an integral single-piece structure. However, in other embodiments, the anisotropic hair-like features 34 and the base structure 32 may be formed as separate components that are attached together. In some embodiments, the base structure 32 and the anisotropic hair-like features 34 are made of polymer material. As an example, the base structure 32 and the anisotropic hair-like features 34 may be made of urethane polymer or silicone rubber. However, any polymer material may be used to fabricate the anisotropic hair-like features 34 and/or the base structure 32. Even polymer material that is very stiff in bulk may be used to fabricate the anisotropic hair-like features 34 since the polymer material will become less stiff when it is fabricated into the small scale anisotropic hair-like features, which results in better adhesive properties for the anisotropic hair-like features.

In an embodiment, the anisotropic hair-like features 34 are arranged on the base structure 32 in the form of an array with symmetrically staggered rows. Thus, each anisotropic hair-like feature 34 in a particular row is relatively positioned between adjacent anisotropic hair-like features of the next row. This arrangement increases the number of anisotropic hair-like features 34 per unit area, which translates into a potentially stronger adhesion between the anisotropic hair-like features and a target object using van der Waals forces.

The anisotropic hair-like features 34 can be configured to have any cross-sectional shape. As an example, the cross-sectional shape of the anisotropic hair-like features 34 may be circular or rectangular. The anisotropic hair-like features 34 may be configured to have a cross-sectional shape that is easier to manufacture. The thickness or the cross-sectional diameter of the anisotropic hair-like features 34 is greater than 50 microns (μm). In some embodiments, the thickness or the cross-sectional diameter of the anisotropic hair-like features 34 is between 100 μm and 500 μm. In other embodiments, the thickness or the cross-sectional diameter of the anisotropic hair-like features 34 is between 200 μm and 400 μm. As an example, the thickness or the cross-sectional diameter of the anisotropic hair-like features 34 may be approximately 380 μm. The length of the anisotropic hair-like features 34 is between 100 μm and 1,000 μm or 1 mm. As an example, the diameter/length ratio of the anisotropic hair-like features 34 can be between and .

The size of the anisotropic hair-like features 34 is an important aspect of the directional adhesive structure 30. In the past, structures that exhibit adhesive properties using van der Waals forces have been researched and developed. These conventional adhesive structures were modeled from biological structures found in nature, such as setae of geckos. Gecko setae include spatulae, which are parts of the setae that engage an object surface for attachment. The spatulae are attached to stalks of the spatulae, which may be attached to thicker stalks. The diameter of the stalks of the setae is in the order of few microns or less. The diameter of the spatulae of the setae is in the order of hundreds of nanometers. Thus, conventional adhesive structures include hair-like structures that are similar in size to the spatulae of gecko setae. Thus, carbon nanotube structures and other nano-sized structures were used as the hair-like structures. However, the size of the hair-like structures made these adhesive structures very difficult and costly to fabricate, which limited commercial application of these conventional adhesive structures.

In contrast, the anisotropic hair-like features 34 of the directional adhesive structure 30 are much larger than the hair-like features of conventional adhesive structures. Thus, the directional adhesive structure 30 is much easier and less expensive to manufacture. In fact, as described below, the directional adhesive structure 30 can be fabricated without using sophisticated fabrication equipments, such as semiconductor processing equipments.

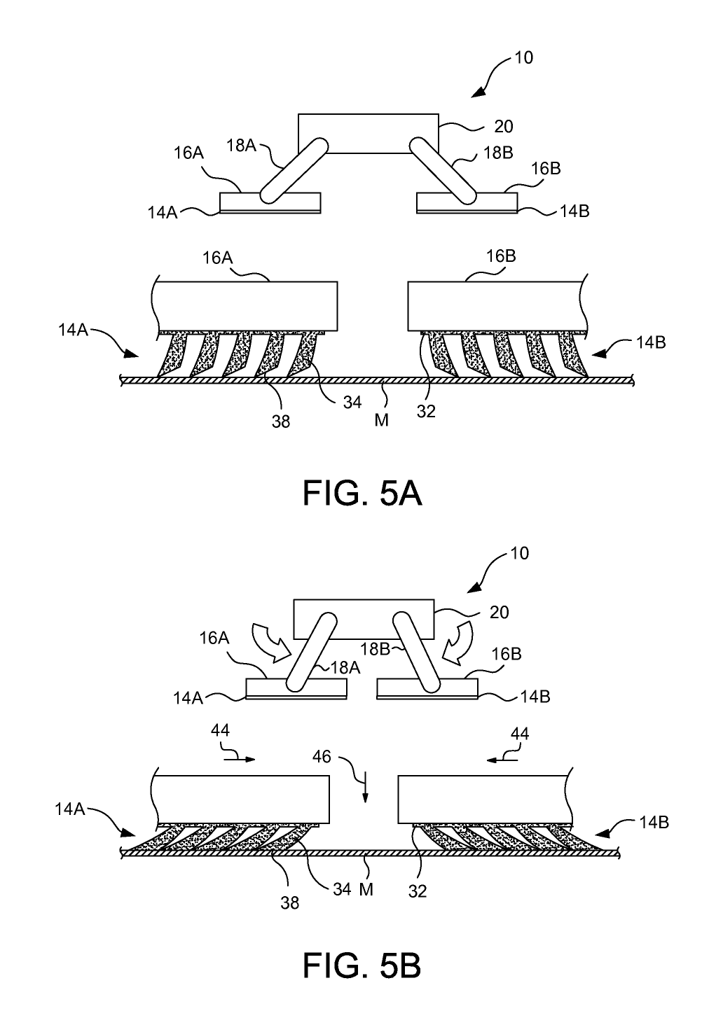

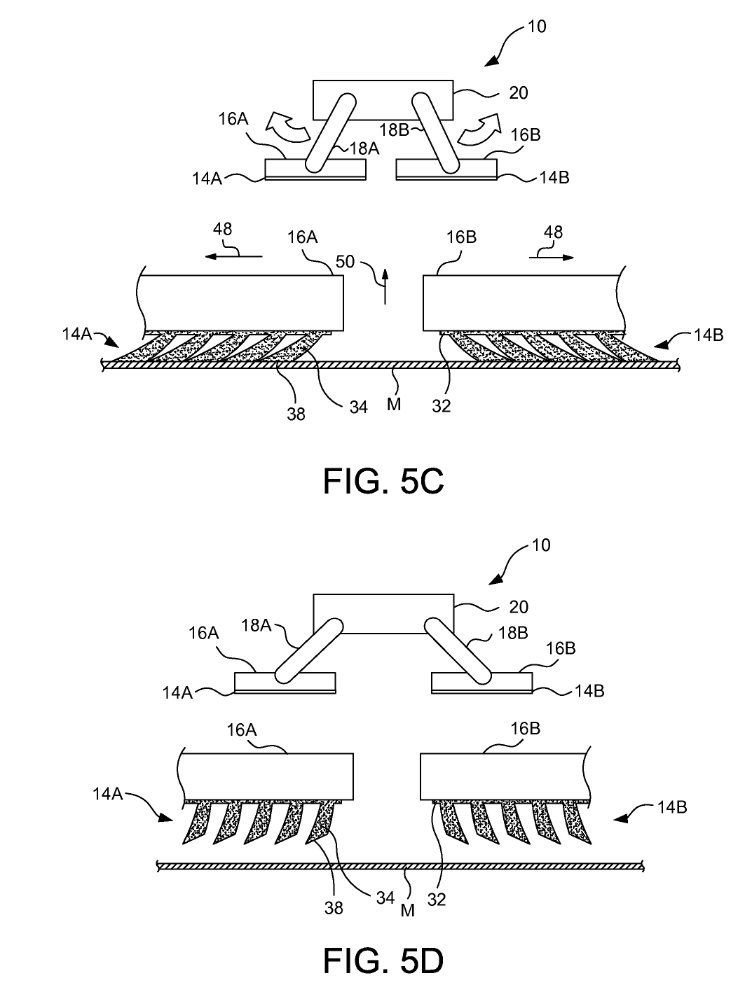

As illustrated in FIG. 5A, the directional adhesive structures 14A and 14B are attached to their respective base plates 16A and 16B such that the contact surfaces 38 of the anisotropic hair-like features 34 of the directional adhesive structure 14A are facing the contact surfaces 38 of the anisotropic hair-like features 34 of the directional adhesive structure 14B. With such orientation of the anisotropic hair-like features 34 of the directional adhesive structures 14A and 14B, the strength of van der Waals forces between the anisotropic hair-like features and a target object M is stronger when tangential forces are applied to the directional adhesive structures toward each other. However, when tangential forces are removed or applied to the directional adhesive structures 14A and 14B away from each other, the strength of van der Waals forces between the anisotropic hair-like features 34 and the target object M is weakened. Consequently, the van der Waals forces between the anisotropic hair-like features 34 and the target object M can be controlled to selectively attach and detach the target object M by controlling the directionality of tangential forces applied to the directional adhesive structures 14A and 14B.

An attaching operation of the object handing module 10 in accordance with an embodiment of the invention is now described with reference to FIGS. 5A and 5B. Initially, the object handing module 10 and/or the object M of interest is/are moved such that tips of the anisotropic hair-like features 34 of the directional adhesive structures 14A and 14B are in contact with a surface of the object M, as illustrated in FIG. 5A. This may be achieved by one or more external mechanisms to move the object handling module 10 and/or the object M. The arms 18A and 18B of the object handing module 10 are then pivoted by the motor 26 directed by the controller 28 to linearly displace the base plates 16A and 16B toward each other, which results in tangential forces being applied to the base structures 32 of the directional adhesive structures 14A and 14B in directions toward each other, as indicated by arrows 44 in FIG. 5B, and a downward force applied to the base structures 32 in a downward direction, as indicated by an arrow 46. Due to the applied tangential forces and the downward force, the angle between the anisotropic hair-like features 34 and the normal line 36 (shown in FIG. 3) is increased, which causes the contact surfaces 38 of the anisotropic hair-like features 34 to contact the object surface. The areas of the contact surfaces 38 of the anisotropic hair-like features 34 contacting the object surface are increased as the applied tangential forces are increased, as illustrated in FIG. 5B, which causes the object M to be attached to the anisotropic hair-like features 34 of the adhesive structures 14A and 14B due to van der Waals forces. The strength of the van der Waals forces between the directional adhesive structures 14A and 14B and the object M can be controlled by the amount of tangential forces being applied to the directional adhesive structures via the arms 18A and 18B.

A detaching operation of the object handing module 10 in accordance with an embodiment of the invention is now described with reference to FIGS. 5B, 5C and 5D. Initially, tangential forces are applied to the directional adhesive structures 14A and 14B toward each other, as illustrated in FIG. 5B, in order to hold the object M using van der Waals forces. To detach or release the object M from the directional adhesive structures 14A and 14B, the tangential forces being applied to the directional adhesive structures 14A and 14B are removed. Alternatively, the arms 18A and 18B of the object handing module 10 are pivoted by the motor 26 directed by the controller 28 to linearly displace the base plates 16A and 16B away from each other, which results in tangential forces being applied to the base structures 32 of the directional adhesive structures 14A and 14B in directions away from each other, as indicated by arrows 48 in FIG. 5C, and an upward force applied to the base structures 32 in a upward direction, as indicated by an arrow 50. The applied tangential forces and the upward force cause the contact surfaces 38 of the anisotropic hair-like features 34 to detach from the object surface to release the object M, as illustrated in FIG. 5D.

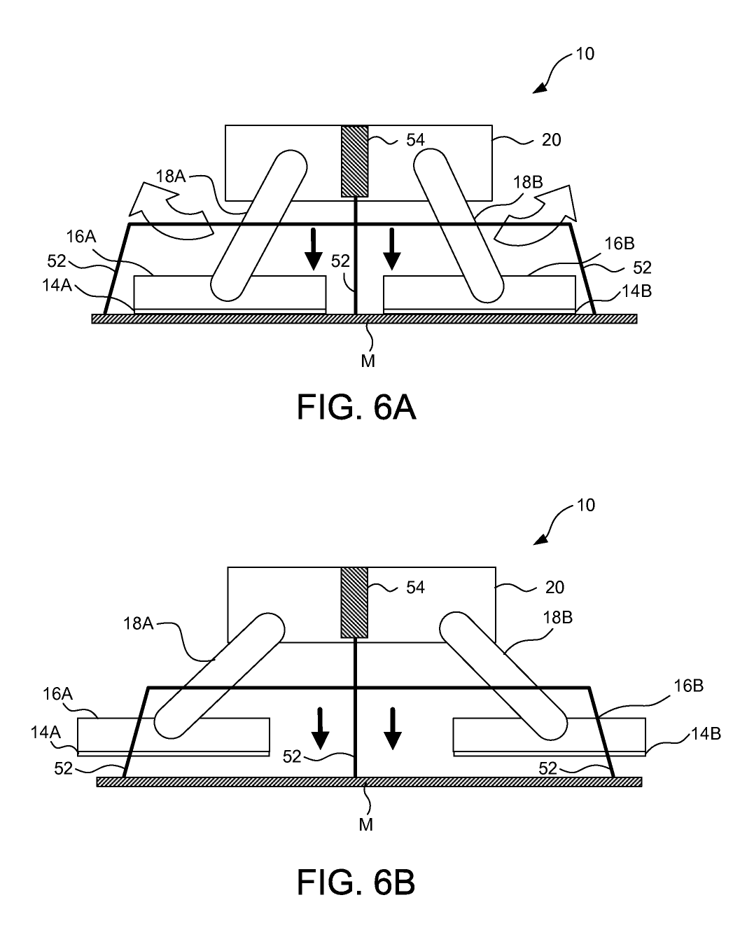

In an alternatively embodiment, as illustrated in FIGS. 6A and 6B, the object handing module 10 may utilize guiding pins 52 to detach the object M from the directional adhesive structures 14A and 14B, which may be useful in releasing the object at a precise location. As shown in FIGS. 6A and 6B, the guiding pins 52 may be connected to an actuator 54, which pushes the guiding pins 50 downward to detach the object M from the directional adhesive structures 14A and 14B. The actuator 54 is attached to the foundation plate 20. In some implementations, the guiding pins 52 and the actuator 54 may be integrated into one or both of the base plates 16A and 16B.

Although the object handing module 10 has been illustrated and described as being configured to attach an object of interest by applying tangential forces to the base plates 16A and 16B toward each other and to detach the object by removing the applied tangential forces or applying tangential forces to the base plates away from each other, the object handing module 10 may be configured to operate in the reverse. That is, the directional adhesive structures 14A and 14B may be attached to their respective base plates 16A and 16B such that the contact surfaces 38 of the anisotropic hair-like features 34 of the directional adhesive structure 14A are facing away from the contact surfaces 38 of the anisotropic hair-like features 34 of the directional adhesive structure 16B. In this embodiment, the object handing module 10 is configured to attach an object of interest by applying tangential forces to the base plates 16A and 16B away from each other and to detach the object by removing the applied tangential forces or applying tangential forces to the base plates toward each other. Furthermore, although a specific embodiment of the object handing module 10 has been illustrated and described, other embodiments of the object handling module are possible without departing from the spirit of the current invention.

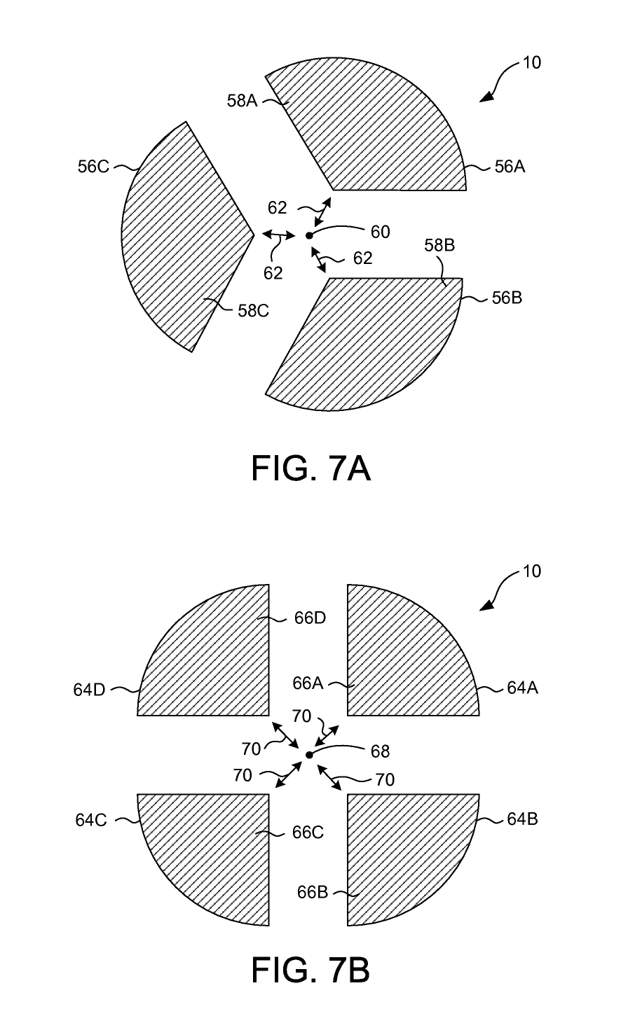

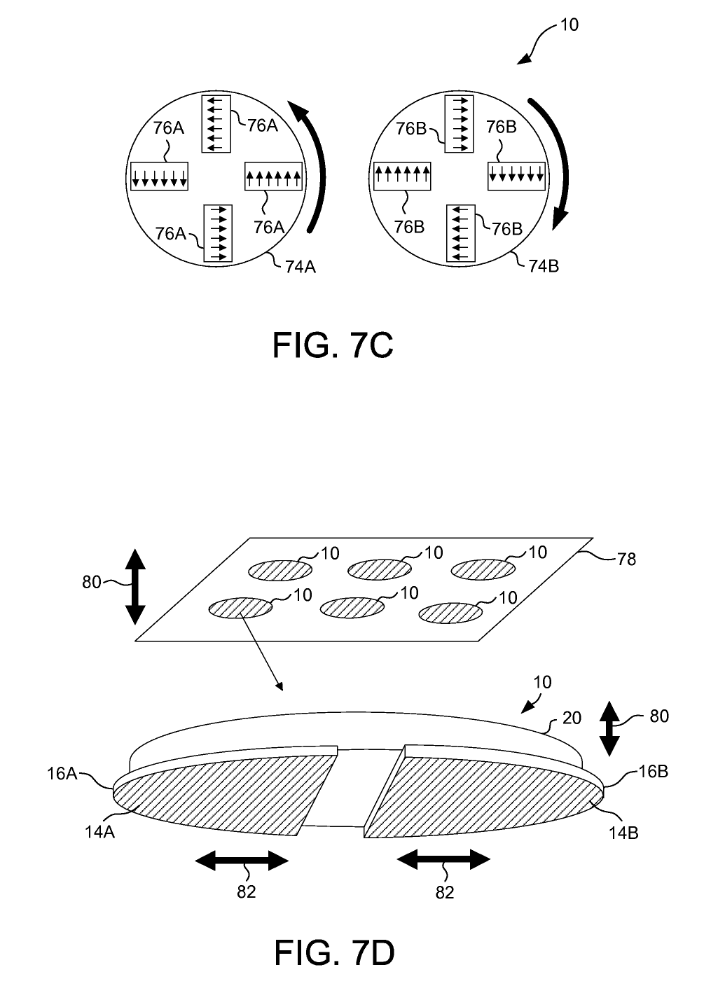

The object handling module 10 of FIG. 2 has been illustrated and described as including two base plates with directional adhesive structures. However, in other embodiments, the object handling module 10 may include more than two base plates with directional adhesive structures, which may be symmetrically positioned about a center point. As an example, the object handing module 10 may include three base plates 56A, 56B and 56C with attached directional adhesive structures 58A, 58B and 58C, as illustrated in FIG. 7A, which is a bottom view of the object handling module. Although not shown, each of the base plates 56A, 56B and 56C is connected to the foundation plate 20 via one or more arms, similar to the arms 18A and 18B shown in FIG. 2. In this example, the base plates 56A, 56B and 56C are connected to apply tangential forces to the attached directional adhesive structures 58A, 58B and 58C, respectively, in radial directions from a center point 60, as indicated by arrows 62. Thus, the anisotropic hair-like features of each of the directional adhesive structures 58A, 58B and 58C should be angled along one of the radial directions toward or away from the center point 60.

As another example, the object handing module 10 may include four base plates 64A, 64B, 64C and 64D with attached directional adhesive structures 66A, 66B, 66C and 66D, as illustrated in FIG. 7B, which is a bottom view of the object handling module. Although not shown, each of the base plates 64A, 64B, 64C and 64D is connected to the foundation plate 20 via one or more arms, similar to the arms 18A and 18B shown in FIG. 2. In this example, the base plates 64A, 64B, 64C and 64D are also connected to apply tangential forces to the attached directional adhesive structures 66A, 66B, 66C and 66D, respectively, in radial directions from a center point 68, as indicated by arrows 70. Thus, the anisotropic hair-like features of each of the directional adhesive structures 66A, 66B, 66C and 66D should be angled along one of the radial directions toward or away from the center point 68.

In addition, although the object handling module 10 of FIG. 2 uses linear tangential forces to attach an object of interest to the directional adhesive structures 14A and 14B, the object handling module 10 in accordance with other embodiments of the invention may use angular tangential forces to attach an object of interest. As an example, the object handling module 10 may include base plates 74A and 74B and a number of directional adhesive structures 76A and 76B, as shown in FIG. 7C. Although the base plates 74A and 74B are illustrated as being circular in shape, the base plates may be configured in any shape, such as a rectangular shape. The directional adhesive structures 76A are attached to the bottom surface of the base plate 74A. Similarly, the directional adhesive structures 76B are attached to the bottom surface of the base plate 74B. Although four directional adhesive structures are shown to be attached to each of the base plates 74A and 74B, any number of directional adhesive structures can be attached to each of the base plates.

In FIG. 7C, the preferred direction of adhesion for the directional adhesive structures 76A and 76B is indicated by arrows on the directional adhesive structures. The preferred direction of adhesion for the directional adhesive structures 76A is the angular counterclockwise tangential direction. Thus, an object of interest can be attached to the directional adhesive structures 76A by applying angular tangential forces to the directional adhesive structures 76A in the counterclockwise direction. The preferred direction of adhesion for the directional adhesive structures 76B is the angular clockwise tangential direction. Thus, the object of interest can be attached to the directional adhesive structures 76B by applying angular tangential forces to the directional adhesive structures 76B in the counterclockwise direction. In operation, the opposite angular directions of tangential forces being applied to an object of interest by the directional adhesive structures 76A and 76B cancel out rotational forces on the object to prevent the object from rotating.

Furthermore, although the object handling module 10 of FIG. 2 was illustrated and described as a single device, the object handling module 10 may be used with other similar or identical object handling modules to handle a large object of interest, such as a large LCD panel, as illustrated in FIG. 7D. The object handling modules 10 may be attached to a large structure 78, which may provide vertical movement of the attached object handling modules, as indicated by an arrow 80. Also, in some embodiments, one or more of the object handling modules 10 may be designed to have a low profile, as illustrated in FIG. 7D. In this embodiment, the base plates 16A and 16B are connected to the foundation plate 20 in close proximity such that the base plates can be linearly displaced without using the pivotable arms 18A and 18B to apply tangential forces to the directional adhesive structures 14A and 14B in linear directions, as indicated by arrows 82. In these embodiments, any drive mechanism that can slide the base plates 16A and 16B along the linear directions can be used.

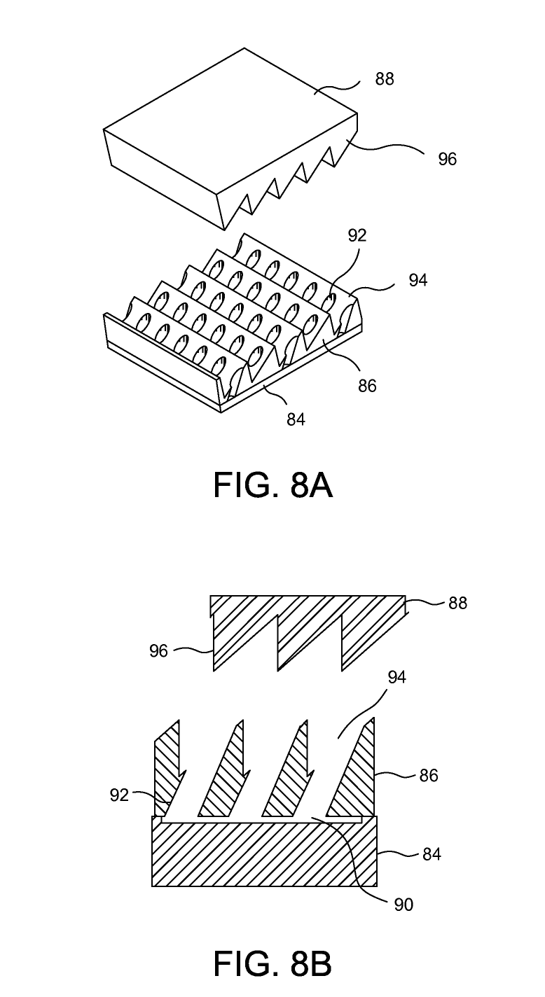

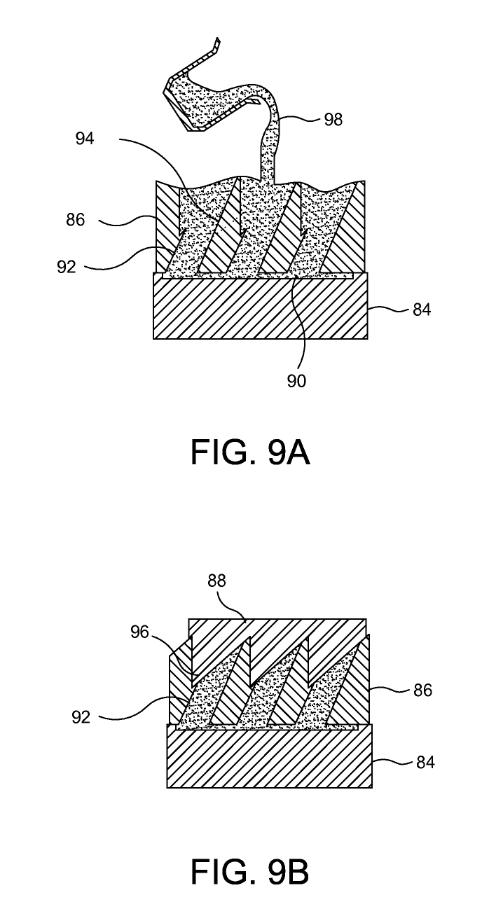

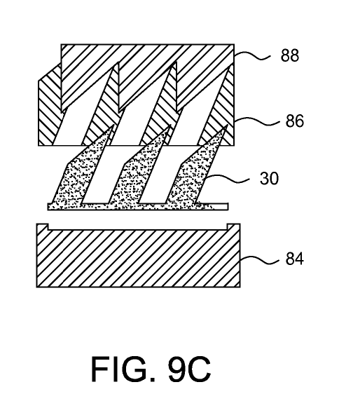

A process of fabricating the directional adhesive structure 30 of FIG. 3 in accordance with an embodiment is now described with reference to FIGS. 8A, 8B, 9A, 9B and 9C. The fabrication process involves using a set of molds, as illustrated in FIGS. 8A and 8B. The mold set includes a base mold 84, a hair-like feature mold 86 and a contact surface mold 88. As illustrated in FIG. 8B, the base mold 84 includes a base space 90, which is used to form the base structure 32 of the directional adhesive structure 30. As illustrated in FIGS. 8A and 8B, the hair-like feature mold 86 includes hair-like feature formation holes 92, which are angled to form the anisotropic hair-like features 34 of the directional adhesive structure 30. The dimensions of the hair-like feature formation holes 92 conform to the anisotropic hair-like features 34 of the directional adhesive structure 30. The hair-like feature mold 86 includes V-shaped grooves 94, which are used to form the angled contact surfaces 38 of the anisotropic hair-like features 34 of the directional adhesive structure 30. Thus, the surfaces of the V-shaped grooves 94 over the hair-like feature formation holes 92 are sloped at the same angle as the contact surfaces 38 of the anisotropic hair-like features 34 of the directional adhesive structure 30. The contact surface mold 88 includes V-shaped protrusions 96, which are configured to conform to the V-shaped grooves 94 of the hair-like feature mold 86. Thus, V-shaped protrusions 96 of the contact surface mold 88 are able to fit into the V-shaped grooves 94 of the hair-like feature mold 86.

The base mold 84, the hair-like feature mold 86 and the contact surface mold 88 are used to fabricate the directional adhesive structure 30 in the following manner. As illustrated in FIG. 9A, liquid polymer 98 is injected into one or more of the hair-like feature formation holes 92 of the hair-like feature mold 86, which is attached to the base mold 84. As a result, the liquid polymer 98 fills the base space 90 of the base mold 84 and the hair-like feature formation holes 92 of the hair-like feature mold 86. Next, as illustrated in FIG. 9B, the contact surface mold 88 is placed on the hair-like feature mold 86 such that the V-shaped protrusions 96 of the contact surface mold 88 are inserted or fitted into the V-shaped grooves 94 of the hair-like feature mold 86. The V-shaped protrusions 96 of the contact surface mold 88 will form the angled contact surfaces 38 of the anisotropic hair-like features 34 of the directional adhesive structure 30.

When the liquid polymer 98 is injected into one or more of the hair-like feature formation holes 92 of the hair-like feature mold 86, the liquid polymer may have not completely filled the base space 90 of the base mold 84, especially near corners due to surface tension. This problem can be resolved by pressing down on the contact surface mold 88 when the contact surface mold is placed on the hair-like feature mold 86 to force the liquid polymer 98 into unfilled regions of the base space 90 of the base mold 84.

After the contact surface mold 88 is placed on the hair-like feature mold 86, the liquid polymer 98 is allowed to cure and solidify. The hair-like feature mold 86 is then separated from the base mold 84 to extract a solidified polymer structure in the form of the directional adhesive structure 30, as illustrated in FIG. 9C.

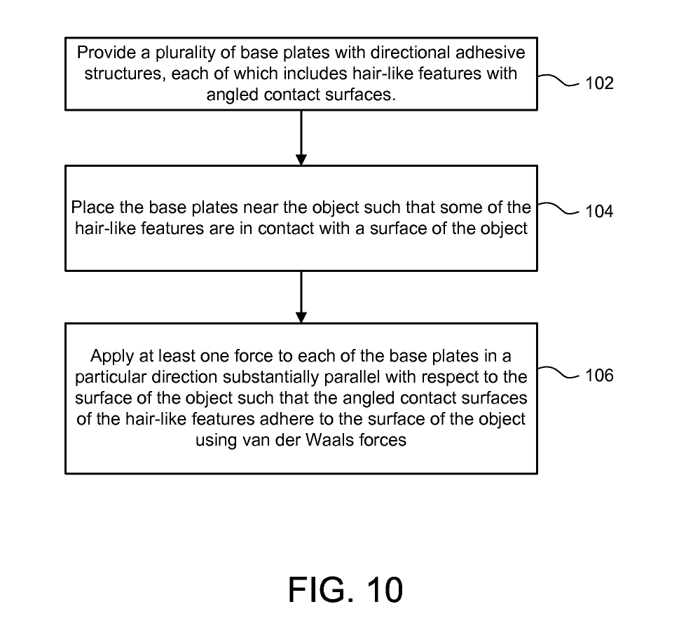

A method of handling an object of interest in accordance with an embodiment of the invention is described with reference to a flow diagram of FIG. 10. At block 102, a plurality of base plates with directional adhesive structures is provided. The directional adhesive structures include hair-like features with angled contact surfaces. Next, at block 104, the base plates are placed near the object such that some of the hair-like features of the directional adhesive structures are in contact with a surface of the object. This can be achieved by moving the base plates and/or the object. Next, at block 106, at least one force is applied to each of the base plates in a particular direction substantially parallel with respect to the surface of the object such that the angled contact surfaces of the hair-like features adhere to the surface of the object using van der Waals forces.

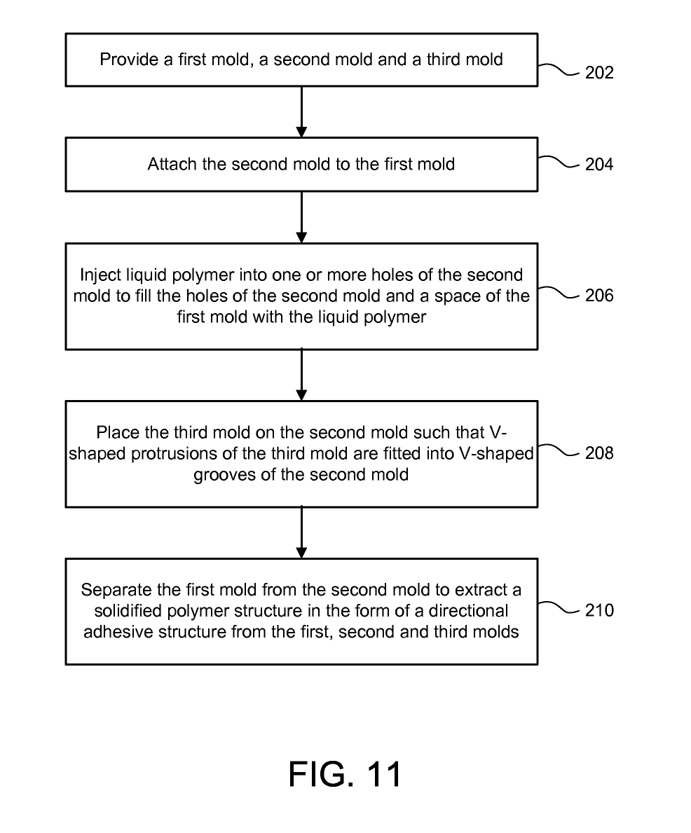

A method of fabricating a directional adhesive structure in accordance with an embodiment of the invention is described with reference to a flow diagram of FIG. 11. At block 202, a first mold, a second mode and a third mold are provided. The first mold includes a space that corresponds to a base structure of the directional adhesive structure. The second mold includes holes that correspond to hair-like features of the directional adhesive structure. The second mold further includes V-shaped grooves, while the third mold includes V-shaped protrusions. Next, at block 204, the second mold is attached to the first mold. Next, at block 206, liquid polymer is injected into one or more of the holes of the second mold to fill the holes of the second mold and the space of the first mold with the liquid polymer. Next, at block 208, the third mold is placed on the second mold such that the V-shaped protrusions of the third mold are fitted into the V-shaped grooves of the second mold. Next, at block 210, the first mold is separated from the second mold to extract a solidified polymer structure in the form of the directional adhesive structure from the first, second and third molds.

Although specific embodiments of the invention have been described and illustrated, the invention is not to be limited to the specific forms or arrangements of parts so described and illustrated. The scope of the invention is to be defined by the claims appended hereto and their equivalents.

1. A device for handling an object of interest, said device comprising:
a plurality of base plates;
a drive mechanism connected to said base plates to apply forces to said base plates; and
a plurality of directional adhesive structures attached to said base plates, each of said directional adhesive structures including a base structure and hair-like features attached to said base structure, said hair-like features having angled contact surfaces such that said angled contact surfaces adhere to a surface of said object using van der Waals forces when at least one force is applied to each of said base plates in a particular direction substantially parallel with respect to an outer surface of said base structure of that base plate.

2. The device of claim 1 wherein some of said hair-like features of said directional adhesive structures have a diameter greater than 50 microns.

3. The device of claim 2 wherein said diameter of some of said hair-like features of said directional adhesive structures is between 100 microns and 500 microns.

4. The device of claim 1 wherein some of said hair-like features of said directional adhesive structures are angled with respect a normal line of said base structure toward an opposite direction of said particular direction.

5. The device of claim 4 wherein the angle between some of said hair-like features and said normal line is between 5 and 45 degrees.

6. The device of claim 1 wherein the angle between said contact surfaces of some of said hair-like features and said normal line is between 10 and 90 degrees.

7. The device of claim 1 wherein the length of some of said hair-like features is between 100 microns and 1000 microns.

8. The device of claim 1 wherein said hair-like features are arranged in an array with symmetrically staggered rows.

9. The device of claim 1 wherein said drive mechanism is configured to apply at least one force to one of said base plates toward another one of said base plates so that said angled contact surfaces of said directional adhesive structures adhere to said object.

10. The device of claim 1 wherein said drive mechanism is configured to apply at least one force to one of said base plates away from another one of said base plates so that said angled contact surfaces of said directional adhesive structures adhere to said object.

11. The device of claim 1 wherein said drive mechanism is configured to apply at least one angular force to one of said base plates so that said angled contact surfaces of said directional adhesive structures adhere to said object.

12. The device of claim 1 wherein said drive mechanism includes a plurality of arms connected to said base plates and a motor operatively connected to said arms to apply said forces to said base plates through said arms.

13. The device of claim 1 wherein said device is integrated into an equipment selected from a group consisting of One Drop Filling (ODF) equipment, Flip-chip packaging equipment, Chip-scale packaging equipment, Micro-Electro-Mechanical-Systems (MEMS) fabrication equipment, semiconductor fabrication equipment, liquid crystal display (LCD) panel fabrication equipment and organic light-emitting diode (OLED) panel fabrication equipment.

14. A method for handling an object of interest, said method comprising:
providing a plurality of base plates with directional adhesive structures, said directional adhesive structures including hair-like features with angled contact surfaces;
placing said base plates near said object such that some of said hair-like features of said directional adhesive structures are in contact with a surface of said object; and
applying at least one force to each of said base plates in a particular direction substantially parallel with respect to said surface of said object such that said angled contact surfaces of said hair-like features adhere to said surface of said object using van der Waals forces.

15. The method of claim 14 further comprising removing said at least one force applied to each of said base plates to release said object from said hair-like features of said directional adhesive structures.

16. The method of claim 14 wherein some of said hair-like features of said directional adhesive structure have a diameter greater than 50 microns.

17. The method of claim 16 wherein said diameter of some of said hair-like features of said directional adhesive structure is between 100 microns and 500 microns.

18. The method of claim 14 wherein the length of some of said hair-like features is between 100 microns and 1000 microns.

19. The method of claim 14 wherein some of said hair-like features of said directional adhesive structure are angled with respect a normal line of a base structure of said directional adhesive structures toward an opposite direction of said particular direction.

20. A directional adhesive structure comprising:
a base structure; and
a plurality of hair-like features attached to said base structure, each of said hair-like features having a contact surface for adhesion using van der Waals forces, said hair-like features having a diameter greater than 50 microns.

21. The structure of claim 20 wherein said diameter of some of said hair-like features is between 100 microns and 500 microns.

22. The structure of claim 20 wherein some of said hair-like features are angled with respect a normal line of said base structure.

23. The structure of claim 20 wherein the length of some of said hair-like features is between 100 microns and 1000 microns.

24. The structure of claim 20 wherein said hair-like features are arranged in an array with symmetrically staggered rows.

25. A method of fabricating a directional adhesive structure, said method comprising:
providing a first mold, a second mold and a third mold, said first mold including a space that corresponds to a base structure of said directional adhesive structure, said second mold including holes that correspond to hair-like features of said directional adhesive structure, said second mold further including V-shaped grooves, said third mold including V-shaped protrusions;
attaching said second mold to said first mold;
injecting liquid polymer into one or more of said holes of said second mold to fill said holes of said second mold and said space of said first mold with said liquid polymer;
placing said third mold on said second mold such that said V-shaped protrusions are fitted into said V-shaped grooves of said second mold; and
separating said first mold from said second mold to extract a solidified polymer structure in the form of said directional adhesive structure from said first, second and third molds.

26. The method of claim 25 wherein some of said holes of said second mold have a diameter greater than 50 microns.

27. The method of claim 26 wherein said diameter of some of said holes of said second mold is between 100 microns and 500 microns.

28. The method of claim 25 wherein the length of some of said holes of said second mold is between 100 microns and 1000 microns.

29. The method of claim 25 wherein some of said holes of said second mold are angled to form said hair-like features of said directional adhesive structure that are angled with respect to a normal line of said base structure.

30. The method of claim 25 wherein said holes of said second mold are arranged in an array with symmetrically staggered rows.
